(19) United States
(12) Patent Application Publication
(10) Pub. No.: US 2025/0096218 A1
(43) Pub. Date: Mar. 20, 2025

(54) SEMICONDUCTOR PACKAGE AND METHOD OF MANUFACTURING THE SAME

(71) Applicant: SAMSUNG ELECTRONICS CO., LTD., Suwon-si (KR)

(72) Inventors: Haseob SEONG, Suwon-si (KR); Aenee JANG, Suwon-si (KR); Dawoon JUNG, Suwon-si (KR)

(73) Assignee: SAMSUNG ELECTRONICS CO., LTD., Suwon-si (KR)

(21) Appl. No.: 18/678,643

(22) Filed: May 30, 2024

(30) Foreign Application Priority Data
Sep. 15, 2023 (KR) 10-2023-0123270

(51) Int. Cl. H01L 25/18; H01L 23/00; H01L 23/48; H01L 23/528

(52) U.S. Cl. CPC H01L 25/18; H01L 23/481; H01L 24/08; H01L 24/32; H01L 23/5283; H01L 24/80; H01L 2224/08145; H01L 2224/08225; H01L 2224/32145; H01L 2224/32225; H01L 2224/80895; H01L 2224/80896; H01L 2225/06544; H01L 2924/1815

(57) ABSTRACT

A semiconductor package including: a base structure including upper and lower surfaces with upper and lower connection pads, the upper connection pad being connected to the lower connection pad; a plurality of first semiconductor chips stacked on the base structure, wherein the plurality of first semiconductor chips includes uppermost and lowermost chips, and wherein each of the plurality of first semiconductor chips includes a first lower and upper pads, and a silicon via connecting the first lower and upper pads; a cover chip, on the uppermost semiconductor chip, including an upper surface with a flat region and an edge region; and an upper dummy chip on the flat region and including an area smaller than an area of the cover chip and a thickness greater than a thickness of the cover chip, wherein the first lower pad of the lowermost chip is connected to the upper connection pad, and wherein the first upper pad of each of the plurality of first semiconductor chips, except for the uppermost chip, is connected to the first lower pad of another first semiconductor chip.

### CROSS-REFERENCE TO RELATED APPLICATION

This application claims priority to Korean Patent Application No. 10-2023-0123270 filed on Sep. 15, 2023, in the Korean Intellectual Property Office, the disclosure of which is incorporated herein by reference in its entirety.

### BACKGROUND

### 1. Field

The present disclosure relates to a semiconductor package and a method of manufacturing the same.

### 2. Description of Related Art

As electronic devices become smaller and lighter according to the development of the electronics industry and the needs of users, semiconductor packages used in electronic devices requires high performance and high capacitance along with miniaturization. In order to achieve high performance and high capacitance with miniaturization, research and development of semiconductor chips including a through silicon via (TSV), and semiconductor packages in which the semiconductor chips are stacked, is continuously being conducted.

### SUMMARY

An aspect of the present disclosure is to provide a semiconductor package having stacked semiconductor chips with improved structural reliability.

An aspect of the present disclosure is to provide a method of manufacturing a semiconductor package having stacked semiconductor chips with improved structural reliability.

According to an aspect of the disclosure, a semiconductor package includes: a base structure including a lower surface with a lower connection pad thereon, and an upper surface with an upper connection pad thereon, wherein the upper connection pad is connected to the lower connection pad; a plurality of first semiconductor chips stacked on the base structure in a vertical direction, wherein the plurality of first semiconductor chips includes an uppermost first semiconductor chip and a lowermost first semiconductor chip, and wherein each of the plurality of first semiconductor chips includes a first lower pad, a first upper pad, and a through silicon via connecting the first lower pad to the first upper pad; a cover chip on the plurality of first semiconductor chips, the cover chip including an upper surface, wherein the upper surface includes a flat region and an edge region having a rounded shape, and wherein the edge region is disposed around the flat region; and an upper dummy chip disposed on the flat region of the cover chip, the upper dummy chip including an area smaller than an area of the cover chip and a thickness greater than a thickness of the cover chip, wherein the first lower pad of the lowermost first semiconductor chip is directly connected to the upper connection pad, and wherein the first upper pad of each of the plurality of first semiconductor chips, except for the uppermost first semiconductor chip, is directly connected to the first lower pad of another first semiconductor chip, among the plurality of first semiconductor chips, adjacent thereto.

According to an aspect of the disclosure, a semiconductor package includes: a base structure including a lower surface with a lower connection pad thereon, and an upper surface with an upper connection pad thereon, wherein the upper connection pad is connected to the lower connection pad; a plurality of first semiconductor chips stacked on the base structure in a vertical direction, wherein the plurality of first semiconductor chips includes an uppermost first semiconductor chip and a lowermost first semiconductor chip, and wherein each of the plurality of first semiconductor chips includes a first lower pad, a first upper pad, and a through silicon via (TSV) connecting the first lower pad and the first upper pad; a second semiconductor chip on the uppermost first semiconductor chip, the second semiconductor chip including: a second lower pad directly bonded to the first upper pad of the uppermost first semiconductor chip; and an upper surface including a flat region and an edge region having a rounded shape, wherein the edge region is disposed around the flat region; and an upper dummy chip on the flat region of the second semiconductor chip, the upper dummy chip including an area smaller than an area of the second semiconductor chip and a thickness greater than a thickness of the second semiconductor chip, wherein the first lower pad of the lowermost first semiconductor chip is directly connected to the upper connection pad, and wherein the first upper pad of each of the plurality of first semiconductor chips, except for the uppermost first semiconductor chip, is directly connected to the first lower pad of another first semiconductor chip, among the plurality of first semiconductor chips, adjacent thereto.

According to an aspect of the disclosure, a semiconductor package includes: a base structure including a lower surface with a lower connection pad thereon, and an upper surface with an upper connection pad thereon, wherein the upper connection pad is connected to the lower connection pad; a plurality of first semiconductor chips stacked on the base structure in a vertical direction, wherein the plurality of first semiconductor chips includes an uppermost first semiconductor chip and a lowermost first semiconductor chip, and wherein each of the plurality of first semiconductor chips includes a first lower pad, a first upper pad, and a through silicon via connecting the first lower pad to the first upper pad; a second semiconductor chip disposed on the uppermost first semiconductor chip, the second semiconductor chip including a second lower pad directly bonded to the first upper pad of the uppermost first semiconductor chip; a lower dummy chip disposed on the second semiconductor chip, the lower dummy chip including an upper surface, wherein the upper surface includes a flat region and an edge region having a rounded shape, and wherein the edge region is disposed around the flat region; and an upper dummy chip disposed on the flat region of the lower dummy chip, the upper dummy chip including an area smaller than an area of the lower dummy chip and a thickness greater than a thickness of the second semiconductor chip, wherein the first lower pad of the lowermost first semiconductor chip is directly bonded to the first upper pad, and wherein the first upper pad of each the plurality of first semiconductor chips, except for the uppermost first semiconductor chip, is directly bonded to the first lower pad of another first semiconductor chip, among the plurality of first semiconductor chips, adjacent thereto.

According to an aspect of the disclosure, a method of manufacturing a semiconductor package includes: providing a base structure having an upper connection pad; sequentially stacking a plurality of first semiconductor chips on the base structure, wherein the plurality of first semiconductor chips includes an uppermost first semiconductor chip and a lowermost first semiconductor chip, and wherein each of the plurality of first semiconductor chips include a first lower pad, a first upper pad, and a first through silicon via electrically connecting the first lower pad and the first upper pad; stacking a cover chip including a first thickness on the uppermost first semiconductor chip; polishing the cover chip to a second thickness thinner than the first thickness and thereby forming a planarized upper surface, wherein the planarized upper surface includes an edge region having a rounded shape; and stacking an upper dummy chip on the planarized upper surface, wherein the upper dummy chip includes an area smaller than an area of the cover chip and a thickness greater than a thickness of the cover chip, wherein the first lower pad of the lowermost first semiconductor chip is directly connected to the first upper pad, and wherein the first upper pad of each of the plurality of first semiconductor chips, except for the uppermost first semiconductor chip, is directly bonded to the first lower pad of another first semiconductor chip, among the plurality of first semiconductor chips, adjacent to an upper portion thereof.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a cross-sectional side view illustrating a semiconductor package according to an example embodiment of the present disclosure;

FIG. 2 is a plan view illustrating the semiconductor package of FIG. 1;

FIGS. 3A and 3B are partially enlarged views illustrating parts “A” and “B” of FIG. 1, respectively;

FIG. 4 is a partially enlarged view illustrating part “C” of FIG. 1;

FIG. 5 is a cross-sectional side view illustrating a semiconductor package according to an example embodiment of the present disclosure;

FIG. 6 is a schematic view illustrating bonding defects of a dummy chip according to a surface topology according to a stack of semiconductor chips;

FIG. 7 is a view illustrating a surface state of an upper surface of a second semiconductor chip of FIG. 5;

FIGS. 8A and 8B are views illustrating surface roughness along an upper surface of the second semiconductor chip of FIG. 7 in an X-axis and a Y-axis, respectively;

FIG. 9 is a view illustrating a surface state of an upper surface of the cover chip of FIG. 5;

FIGS. 10A and 10B are views illustrating surface roughness along an upper surface of the cover chip of FIG. 9 in the X-axis and Y-axis, respectively;

FIG. 11 is a cross-sectional side view illustrating a semiconductor package according to an example embodiment of the present disclosure;

FIG. 12 is a partially enlarged view illustrating part “D” of FIG. 11;

FIGS. 13A, 13B, 13C, 13D and 13E are cross-sectional views for each main process for explaining a method of manufacturing a semiconductor chip adopted in an example embodiment of the present disclosure;

FIGS. 14A, 14B, 14C, 14D, 14E, 14F and 14G are cross-sectional views for each main process for explaining a method of manufacturing a semiconductor package according to an example embodiment of the present disclosure; and

FIG. 15 is a flow chart describing a method of manufacturing a semiconductor package according to an example embodiment of the present disclosure.

### DETAILED DESCRIPTION

As used herein, it will be understood that when an element is referred to as being “connected” with or to another element, it can be directly or indirectly connected to the other element. Similarly, when a member is “on” another member, this includes not only when the member is in contact with the other member, but also when there is another member between the two members.

Also, when a part “includes” or “comprises” an element, unless there is a particular description contrary thereto, the part may further include other elements, not excluding the other elements.

Herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms first, second, third, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

Hereinafter, example embodiments of the present disclosure will be described with reference to the accompanying drawings.

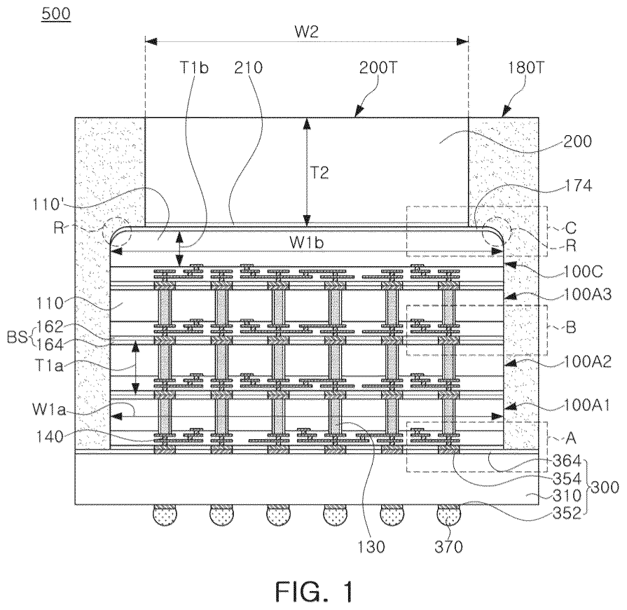

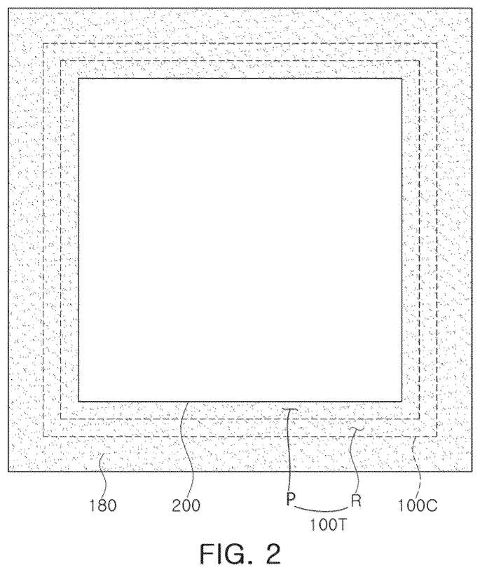

FIG. 1 is a side cross-sectional view illustrating a semiconductor package according to an example embodiment of the present disclosure, and FIG. 2 is a plan view illustrating the semiconductor package of FIG. 1.

Referring to FIG. 1, a semiconductor package 500 according to an example embodiment of the present disclosure may include a base structure 300, a plurality of semiconductor chips 100A1, 100A2, 100A3 and 100C stacked on the base structure 300 in a vertical direction, and an upper dummy chip 200 disposed on the stack of the plurality of semiconductor chips 100A1, 100A2, 100A3 and 100C.

In this example embodiment, the plurality of stacked semiconductor chips may include three first semiconductor chips 100A1, 100A2 and 100A3 and a cover chip 100C thereon. A plurality of first semiconductor chips 100A1, 100A2, and 100A3 may have the same area. Furthermore, the cover chip 100C may also have the same area as an area of each of the first semiconductor chips 100A1, 100A2 and 100A3. The cover chip 100C adopted in the present example embodiment may include a second semiconductor chip. For example, as illustrated in FIG. 1, the plurality of first semiconductor chips 100A1, 100A2 and 100A3 may have the same width W1a and the same thickness T1a. Furthermore, a width W1b of the cover chip 100C may be the same as the width W1a of each of the first semiconductor chips 100A1, 100A2 and 100A3.

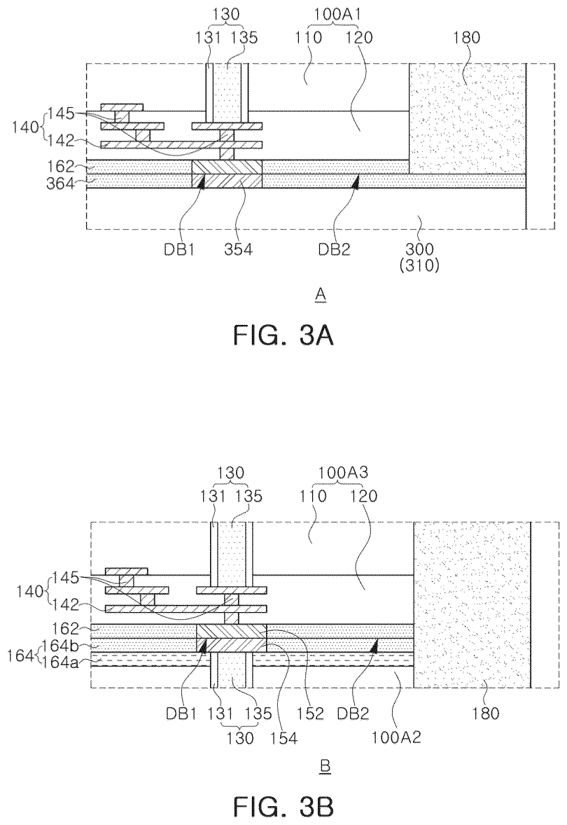

FIGS. 3A and 3B are partially enlarged views illustrating parts “A” and “B” of FIG. 1, respectively.

Referring to FIG. 1, together with FIGS. 3A and 3B, the plurality of first semiconductor chips 100A1, 100A2 and 100A3 may include a semiconductor substrate 110 having a first surface (also referred to as an “active surface”) and a second surface (also referred to as a “non-active surface”) disposed opposite to each other, a device layer 120 on the first surface of the semiconductor substrate 110, a through silicon via (TSV) 130 penetrating through the semiconductor substrate 110, lower pads 152 on the device layer 120 (i.e., a lower surface of the first semiconductor chip), and upper pads 154 on the second surface of the first semiconductor chip 100A1 (i.e., an upper surface of the first semiconductor chip).

For example, the semiconductor substrate 110 may include silicon. The semiconductor substrate 110 may include various impurity regions for individual devices and a device isolation structure such as a shallow trench isolation (STI) structure.

The device layer 120 may include a wiring structure 140 connected to a plurality of individual devices formed on the active surface of the semiconductor substrate 110. As illustrated in FIGS. 3A and 3B, the wiring structure 140 may include a metal wiring layer 142 and a metal via 145. For example, a multilayer wiring structure 140 may be a multilayer structure that includes two or more metal wiring layers 142 and/or two or more vias 145. The wiring structure 140 may be connected to lower pads 152 disposed on upper surfaces of the first semiconductor chips 100A1, 100A2 and 100A3.

Each of the through silicon vias (TSV) 130 may have a pillar structure penetrating through the semiconductor substrate 110. An upper end of the through silicon via (TSV) 130 may be connected to the upper pads 154, and a lower end thereof may be connected to the lower pads 152 through the wiring structure 140. In this manner, the through silicon via (TSV) 130 may electrically connect the lower pads 152 and the upper pads 154, respectively. The through silicon via (TSV) 130 may include a via plug 135 and an insulating liner 131 surrounding the via plug 135. The insulating liner 131 may electrically separate the via plug 135 from the semiconductor substrate 110.

In an example embodiment, an uppermost second semiconductor chip 100C of the chip stack may include a semiconductor substrate 110, a device layer 120, and lower pads 152, similarly to the first semiconductor chips 100A1, 100A2 and 100A3, except that there are no corresponding elements of the through silicon via (TSV) 130 and the upper pads 154. In an embodiment, the second semiconductor chip 100C may be configured to perform the same function (e.g., a memory) as the first semiconductor chips 100A1, 100A2 and 100A3.

The upper pads 154 of the plurality of first semiconductor chips 100A1, 100A2 and 100A3 may be directly bonded to lower pads 152 of other first semiconductor chips 100A2 and 100A3 or another second semiconductor chip 100C adjacent to an upper portion thereof.

For example, referring to FIG. 3B, the upper pads 154 and the lower pads 152 are directly bonded between adjacent first semiconductor chips 100A2 and 100A3 to form an intermetallic bonding DB1. The intermetallic bonding DB1 may mechanically fix the adjacent first semiconductor chips 100A2 and 100A3 to each other, and may simultaneously provide a path for transmitting and receiving at least one of a control signal, a power signal, a ground signal, and a data signal. Specifically, since the intermetallic bonding DB1 of the upper pads 154 and the lower pads 152 does not use additional conductive bumps such as a solder, a transmission loss may be reduced.

As described above, the plurality of first semiconductor chips 100A1, 100A2 and 100A3 and the second semiconductor chip 100C may be electrically connected to each other by the intermetallic bonding DB1 of the upper pads 154 and the lower pads 152.

The upper pads 154 and the lower pads 152 may include the same metal, for example, copper (Cu). After the upper pads 154 and the lower pads 152 are pre-bonded to make direct contact, they may be firmly bonded by mutual diffusion of copper through a high-temperature annealing process. A metal forming the upper pads 154 and the lower pads 152 is not limited to copper, and may include other metallic materials (e.g., Au) capable of being mutually bonded.

In an example embodiment, a bonding structure BS between adjacent semiconductor chips may include “inter-dielectric bonding DB2” in addition to the metal bonding DB1 described above. As illustrated in FIG. 3B, the inter-dielectric bonding DB2 may be formed by directly bonding an upper insulating layer 164 on the first semiconductor chips 100A1, 100A2 and 100A3 and a lower insulating layer 162 of other first semiconductor chips 100A2 and 100A3 or a second semiconductor chip 100C adjacent to an upper portion thereof. The upper insulating layer 164 and the lower insulating layer 162 may be formed of the same material. For example, the upper insulating layer 164 and the lower insulating layer 162 may include silicon oxide. The inter-dielectric bonding DB2 of the upper insulating layer 164 and the lower insulating layer 162 may be implemented by covalent bonding. The bonding structure BS may have more robust bonding strength due to the inter-dielectric bonding DB2. An insulating material forming the upper insulating layer 164 and the lower insulating layer 162 is not limited to silicon oxide, but may include all materials that may be bonded to each other (e.g., SiCN).

In an embodiment, The upper insulating layer 164 may include a first insulating film 164a and a second insulating film 164b sequentially disposed on upper surfaces of the first semiconductor chips 100A1, 100A2 and 100A3, as illustrated in FIG. 3B. The first insulating film 164a may have an upper surface substantially coplanar with an upper end of the through silicon via (TSV) 130. The upper pads 154 may be formed on the first insulating film 164a to be connected to the through silicon via (TSV) 130. The first insulating film 164a may prevent an undesired electrical connection between the upper pads 154 and the semiconductor substrate 110. Furthermore, the upper pads 154 may be buried in the second insulating film 164b so that an upper surface thereof is exposed. The exposed upper surfaces of the upper pads 154 may have a upper surface substantially coplanar with an upper surface of the second insulating film 164b. In an embodiment, the first and second insulating layers 164a and 164b may be formed of the same material, but the present disclosure is not limited thereto and the first and second insulating layers 164a and 164b may be formed of other materials. For example, the first insulating film 164a may include silicon nitride or silicon oxynitride, and the second insulating film 164b may include silicon oxide.

As described above, in this example embodiment, the bonding structure BS for a connection between chips may include the intermetallic bonding DB1 between the lower pad 152 and the upper pad 154, and the inter-dielectric bond DB2 of the lower insulating layer 162 and the upper insulating layer 164.

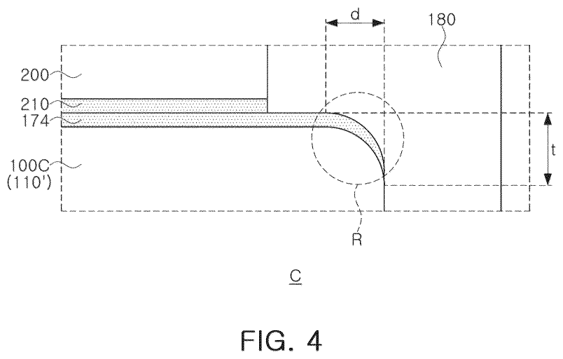

The second semiconductor chip 100C adopted in this example embodiment is a cover chip of the chip stack, and may be configured to have the same or a similar function as the first semiconductor chips 100A1, 100A2 and 100A3, as described above. Referring to FIGS. 1 and 4, the second semiconductor chip 100C has a width W1b identical to a width W1a of the first semiconductor chips 100A1, 100A2 and 100A3, and has a thickness T1b identical to or similar to a thickness T1a of the first semiconductor chips 100A1, 100A2 and 100A3, but have an upper surface 100T of a different shape. The upper surface 100T of the second semiconductor chip 100C adopted in this example embodiment includes a flat region P and an edge region R having a rounded shape around the flat region P. Here, a similar thickness range is not limited thereto, but may be defined as a thickness deviation in the range of +30%.

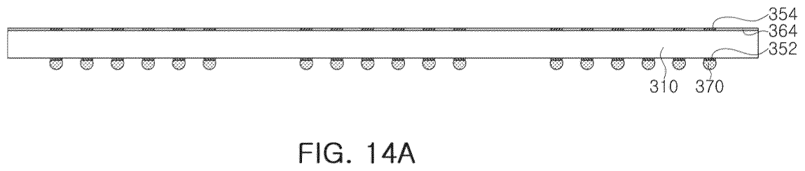

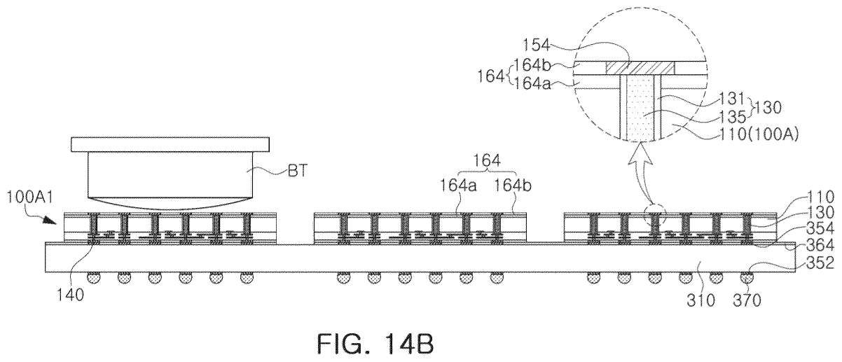

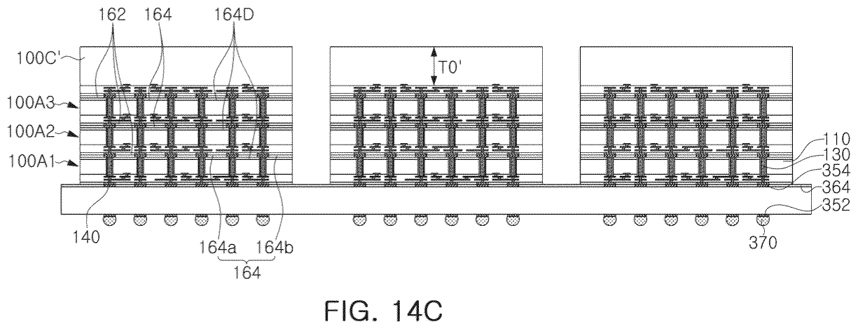

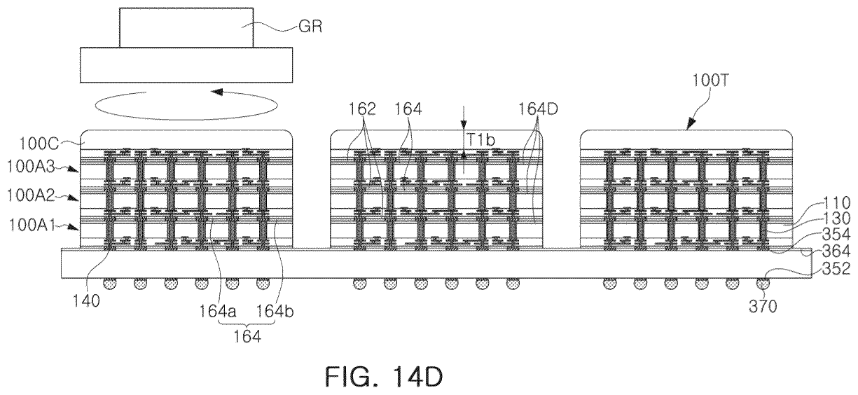

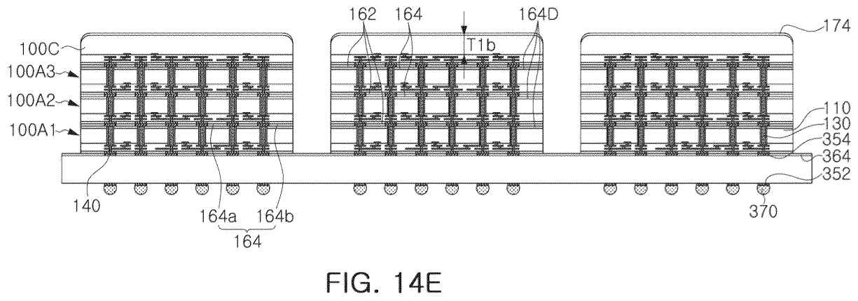

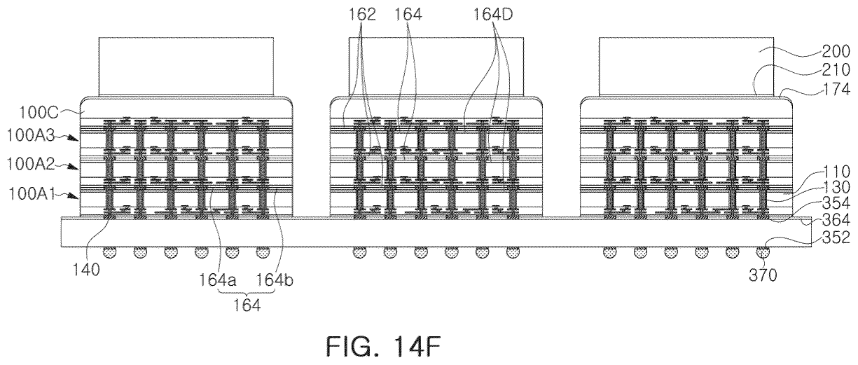

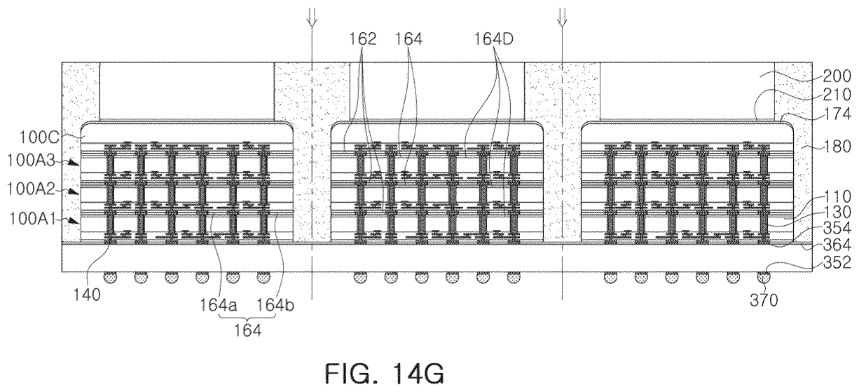

The upper surface 100T of the second semiconductor chip 100C may be understood as an upper surface obtained through a polishing process while being disposed at an uppermost portion of the chip stack (see FIG. 14D). During the polishing process, a main region P of the upper surface 100T of the second semiconductor chip 100C is planarized (or flat), but the edge region R of the upper surface 100T may have a rounded shape.

As illustrated in FIG. 4, the rounded edge region R is provided on a semiconductor substrate 110′, and an upper insulating layer 174 is formed after the polishing process. Accordingly, the upper insulating layer 174 may extend along the rounded edge region R on the upper surface of the semiconductor substrate 110′. For example, a width d of the rounded edge region R may range from 50 μm to 1000 μm. For example, a depth t of the rounded edge region R may range from 100 Å to 1000 Å. The present disclosure is not limited thereto, and a size of the rounded edge region R may be variously changed according to polishing process conditions.

Since the thickness T1a of the first semiconductor chips 100A1, 100A2 and 100A3 are thin (e.g., 100 μm or less), surface topologies of each chip may be accumulated in the process of stacking the first semiconductor chips 100A1, 100A2 and 100A3, thereby greatly increasing a surface topology of the uppermost semiconductor chip 100A3. In an embodiment, the second semiconductor chip 100C may have a flat region P formed by polishing an upper surface of the second semiconductor chip 100C while the second semiconductor chip 100C is stacked (i.e., bonded to the uppermost semiconductor chip of the first semiconductor chips).

As illustrated in FIGS. 1 and 2, the semiconductor package 500 according to this example embodiment may include an upper dummy chip 200 disposed on the flat region P of the second semiconductor chip 100C. For example, the upper dummy chip 200 may include a semiconductor such as silicon or a substrate such as metal. In an embodiment, the upper dummy chip 200 may provide a heat dissipation function and/or an identification mark display region.

The upper dummy chip 200 may include a lower bonding insulating layer 210 disposed on a lower surface thereof, and the second semiconductor chip 100C may include an upper insulating layer 174 disposed on an upper surface thereof. By directly bonding the lower bonding insulating layer 210 and the upper insulating layer 174, the upper dummy chip 200 may be bonded to the upper surface 100T of the second semiconductor chip 100C. As described above, the upper dummy chip 200 and the second semiconductor chip 100C may be bonded by an inter-dielectric bonding between the lower bonding insulating layer 210 and the upper insulating layer 174. At least one of the lower bonding insulating layer 210 and the upper insulating layer 174 may include a dielectric layer formed by a deposition process, but may alternatively include a natural oxide film formed in a high-temperature annealing process.

In an example embodiment, the upper dummy chip 200 may be disposed within the flat region P so that the upper dummy chip 200 is not disposed in a round region R of the second semiconductor chip 100C. A width W2 (i.e., part of an area) of the upper dummy chip 200 may be less than a width W1b (i.e., part of an area) of the second semiconductor chip 100C.

As described above, even if the upper dummy chip 200 has a relatively large thickness T2, as described above, since the second semiconductor chip 100C has the flat region P (see FIG. 2), the second semiconductor chip 100C may form a solid bond with the upper dummy chip 200 without bonding defects such as a void in the flat region P.

In an example embodiment, the base structure 300 may include lower connection pads 352 disposed on the lower surface of the base structure, and upper connection pads 354 disposed on the upper surface of the base structure. In this example embodiment, the base structure 300 may have a width (i.e., an area) greater than widths W1a and W1b (i.e., an area) of the first semiconductor chips 100A1, 100A2, and 100A3 and the second semiconductor chip 100C.

A lowest semiconductor chip 100A1 among the first semiconductor chips 100A1, 100A2 and 100A3 may be directly bonded to the base structure 300 via a bonding structure similar to bonding structure BS described above.

Specifically, referring to FIG. 3A, the lower pads 152 of the first semiconductor chip 100A1 adjacent to the base structure 300 may be directly bonded to the upper connection pads 354 to form an intermetallic bonding DB1. The intermetallic bonding DB1 may bond the base structure 300 and the first semiconductor chip 100A1 to each other while ensuring an electrical connection. An upper bonding insulating layer 364 may be formed on an upper surface of the base structure 300 adopted in this example embodiment, and the upper bonding insulating layer 364 may have an upper surface substantially coplanar with upper surfaces of the upper connection pads 354. The upper bonding insulating layer 364 of the base structure 300 and a lower insulating layer 162 of a lowermost semiconductor chip 100A1 may be directly bonded to form an inter-dielectric bonding DB2. In this manner, the base structure 300 and the lowest semiconductor chip 100A1 may be hybrid-bonded, similarly to the bonding structure BS described above.

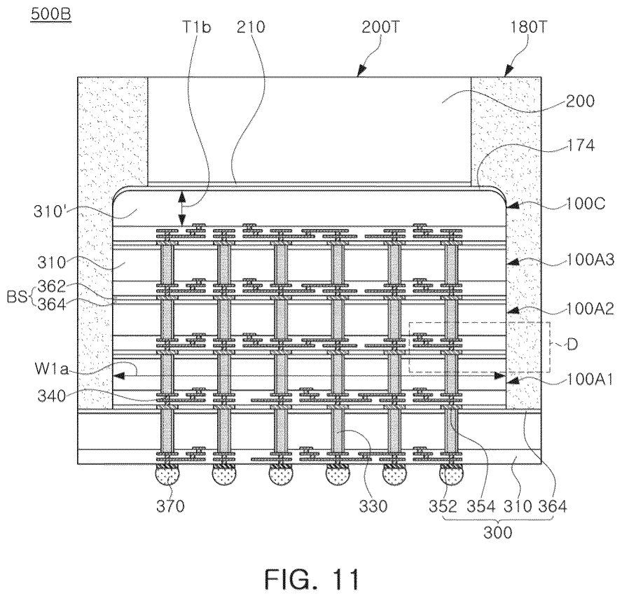

The base structure 300 adopted in this example embodiment may be an interposer for redistribution. In an embodiment, the base structure 300 may include a substrate main body 310 and a wiring circuit for connecting lower connection pads 352 and upper connection pads 354 in the substrate main body 310. A connection bump 370 may be attached to the lower connection pads 352 of the base structure 300. The connection bump 370 may be, for example, a solder ball or a conductive bump. The connection bump 370 may be electrically connected to the semiconductor package 500 and a printed circuit board such as a mother board. In an embodiment, the base structure 300 may include a semiconductor chip (see FIG. 11).

The first semiconductor chips 100A1, 100A2, and 100A3 and the second semiconductor chip 100C may be memory chips. For example, the memory chip may be a volatile memory chip such as a dynamic random access memory (DRAM) or a static random access memory (SRAM), or a non-volatile memory chip such as a phase-change random access memory (PRAM), a magnetoresistive random access memory (MRAM), a ferroelectric random access memory (FeRAM) or a resistive random access memory (RRAM). In this example embodiment, the first semiconductor chips 100A1, 100A2, 100A3 and the second semiconductor chip 100C may all be the same type of memory chip. For example, the first semiconductor chips 100A1, 100A2, and 100A3 and the second semiconductor chip 100C may be a high bandwidth memory (HBM) DRAM.

In an embodiment, some of the first semiconductor chips 100A1, 100A2, and 100A3 and the second semiconductor chip 100C may be memory chips, and others thereof may be logic chips. The logic chip may be, for example, a microprocessor, an analog device, or a digital signal processor.

A molding portion 180 may be disposed on the base structure 300 to surround the first semiconductor chips 100A1, 100A2, and 100A3, the second semiconductor chip 100C, and the upper dummy chip 200. For example, the molding portion 180 may include an epoxy mold compound (EMC).

An upper surface 200T of the upper dummy chip 200 is exposed to an upper surface 180T of the molding portion 180. The exposed upper surface 200T of the upper dummy chip 200 may have an upper surface, substantially coplanar with the upper surface 180T of the molding portion 180. Such coplanar upper surfaces may be understood as upper surfaces obtained through a polishing process. Furthermore, the molding portion 180 may have side surfaces, substantially coplanar with side surfaces of the base structure 300. Such coplanar side surfaces can be understood as aspects obtained through a cutting process. As illustrated in FIG. 1, a width of a part of the molding portion 180 disposed on a side surface of the upper dummy chip 200 may be greater than a width of a part of the molding portion 180 disposed on a side surface of the first semiconductor chips 100A1, 100A2, and 100A3 and second semiconductor chip 100C.

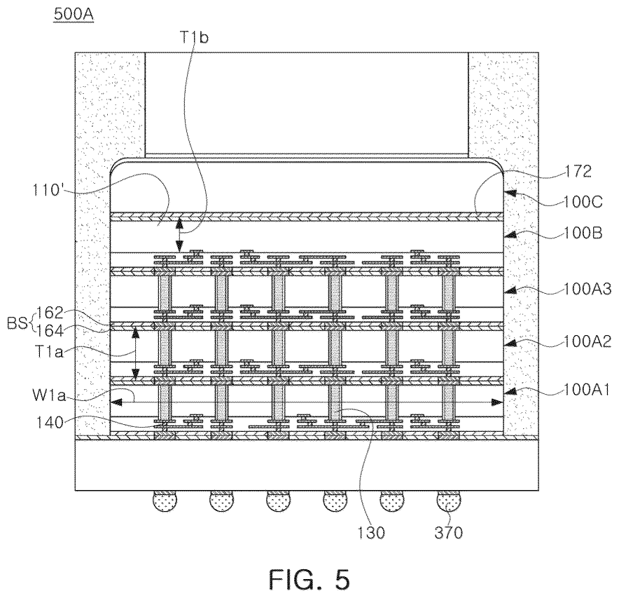

In the above-described example embodiment, the cover chip exemplifies the form provided as a semiconductor chip performing a specific function, but in an embodiment, the cover chip may be provided as a dummy chip having the planarized region (see FIG. 5).

FIG. 5 is a side cross-sectional view illustrating a semiconductor package according to an example embodiment of the present disclosure.

Referring to FIG. 5, a semiconductor package 500A according to an example embodiment may be understood to be a structure similar to that of the example embodiment illustrated in FIGS. 1 to 4, except that a cover chip 100C is provided as a dummy chip (referred to as a “lower dummy chip”), and a second semiconductor chip 100B is provided between the cover chip 100C and first semiconductor chips 100A1, 100A2 and 100A3. Accordingly, the description of an example embodiment illustrated in FIGS. 1 to 4 may be combined with the description of this example embodiment unless otherwise described.

The first semiconductor chips 100A1, 100A2 and 100A3 used in an example embodiment may each include a semiconductor substrate 110, a device layer 120, through silicon vias 130, lower pads 152, and upper pads 154, similarly to the first semiconductor chips of the previous example embodiment. Furthermore, the first semiconductor chips 100A1, 100A2 and 100A3 may include a lower insulating layer 162 surrounding the lower pads 152 on an inactive surface of the semiconductor substrate 110, and an upper insulating layer 164 surrounding the upper pads 154 on the device layer 120. The upper pads 154 and the upper insulating layer 164 of the first semiconductor chips 100A1 and 100A2 may be directly bonded to the lower pads 152 and the lower insulating layer 162 of the first semiconductor chips 100A2 and 100A3 adjacent to an upper portion thereof (see FIG. 3B). Similarly thereto, the lower pads 152 and the lower insulating layer 162 of a lowermost first semiconductor chip 100A1 may be directly bonded to the upper connection pads 354 and the upper bonding insulating layer 364 of the base structure 300, respectively (see FIG. 3A).

The second semiconductor chip 100B has a structure similar to that of the second semiconductor chip 100C of the previous example embodiment, but does not have a rounded edge region. The second semiconductor chip 100B is disposed on an uppermost semiconductor chip 100A3 among the first semiconductor chips 100A1, 100A2 and 100A3. The upper pads 154 and the upper insulating layer 164 of the second semiconductor chip 100B may be directly bonded to the lower pads 152 and the lower insulating layer 162 of the uppermost semiconductor chip 100A3, respectively. The second semiconductor chip 100B has the same width as each of the first semiconductor chips 100A1, 100A2 and 100A3, and the second semiconductor chip 100B may have a thickness identical to or similar to the thickness of each of the first semiconductor chips 100A1, 100A2 and 100A3.

In an embodiment, an additional cover chip 100C may be introduced to the second semiconductor chip 100B. The cover chip 100C adopted in this example embodiment may be a lower dummy chip that does not have elements such as a device layer. An upper surface of the lower dummy chip 100C may have a flat region P and an edge region R having a rounded shape around the flat region P. The lower dummy chip 100C includes a lower insulating layer 172 on a lower surface thereof and an upper insulating layer 174 on an upper surface thereof. The lower insulating layer 172 of the lower dummy chip 100C may be directly bonded to the upper insulating layer 164 of the second semiconductor chip.

The semiconductor package 500 according to an example embodiment may include an upper dummy chip 200 disposed on the flat region P of the lower dummy chip 100C. The upper dummy chip 200 may have a thickness greater than a thickness of the lower dummy chip 100C as well as a thicknesses of the second semiconductor chip 100B and the first semiconductor chips 100A1, 100A2, and 100A3. For example, the thickness of the upper dummy chip 200 may be 200 μm or more.

The upper dummy chip 200 includes a lower bonding insulating layer 210 disposed on a lower surface thereof, and the lower bonding insulating layer 210 may be directly bonded to the upper insulating layer 174 to be bonded to the upper dummy chip 200 and the cover chip 100C. In an example embodiment, since the upper dummy chip 200 has a relatively small width (or an area), the upper dummy chip 200 is not disposed in the round region R of the second semiconductor chip 100C, and may be disposed in a flat region P.

As described above, even if the upper dummy chip 200 has a relatively large thickness, the lower dummy chip 100C may be disposed on the flat region P, thereby firmly bonding the upper dummy chip 200 and the lower dummy chip 100C without introducing bonding defects such as voids.

The semiconductor packages 500 and 500A according to the above-described example embodiments are illustrated as having a stack of four semiconductor chips, but the number of stacked semiconductor chips is not limited thereto. For example, as chip stacks, more than four stacks of semiconductor chips (e.g., 12) may be stacked.

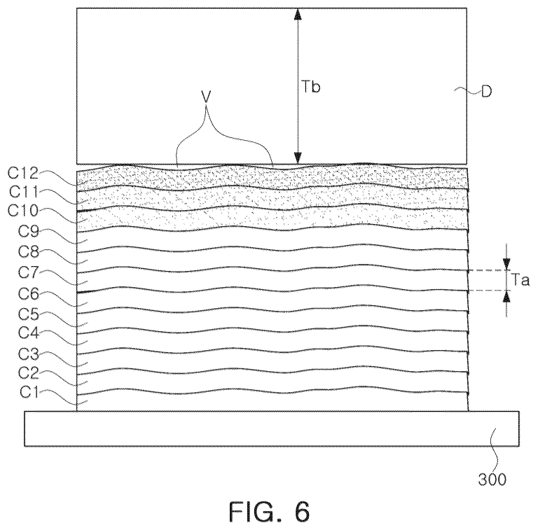

FIG. 6 is a schematic view illustrating bonding defects of a dummy chip according to a surface topology according to a stack of semiconductor chips.

Referring to FIG. 6, because a thickness Ta of each of semiconductor chips C1 to C12 is very thin (e.g., about 50 μm), as the number of semiconductor chips stacked by hybrid bonding (metal+dielectric) increases, a surface topology of an uppermost semiconductor chip C12 is accumulated and increased. When a dummy chip D having a relatively large thickness Tb (e.g., 250 μm or more) is bonded to a surface of the uppermost semiconductor chip C12, because the dummy chip D may be less flexible due to the large thickness, the dummy chip D may find it difficult to be sufficiently contacted and bonded thereto as compared to other thin semiconductor chips C1 to C12. Accordingly, the thick dummy chip D may cause bonding defects, such as voids, with a surface of a stack of hybrid bonded semiconductor chips.

In order to solve the surface topology of the uppermost semiconductor chip C12, a cover chip may be introduced, and a flat region for bonding the thick dummy chips may be provided by polishing the cover chip in a stacked state.

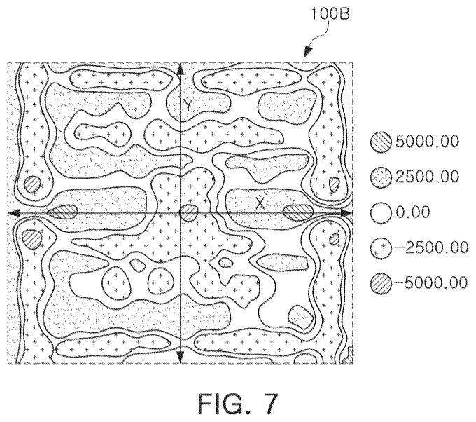

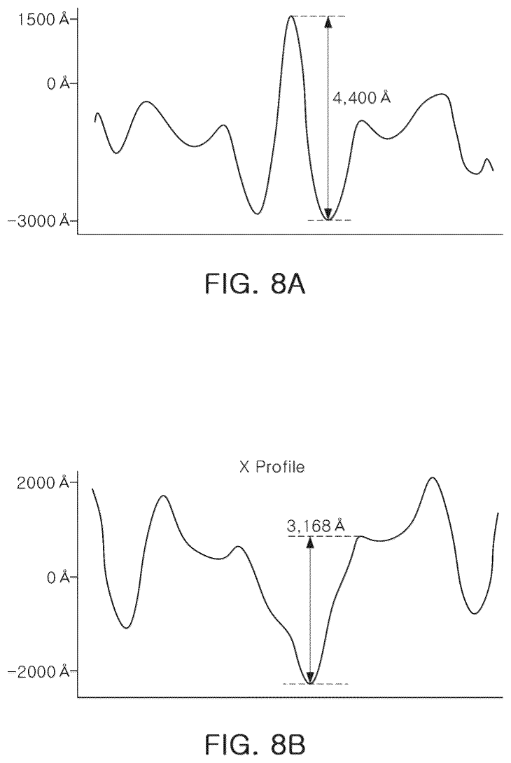

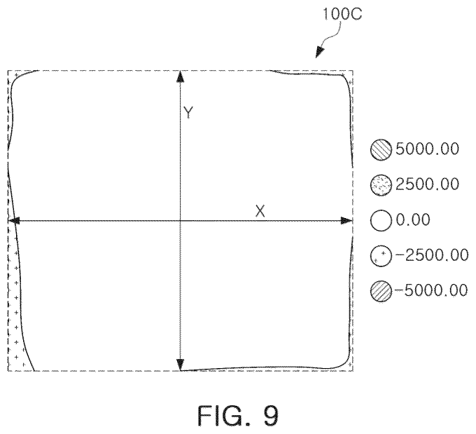

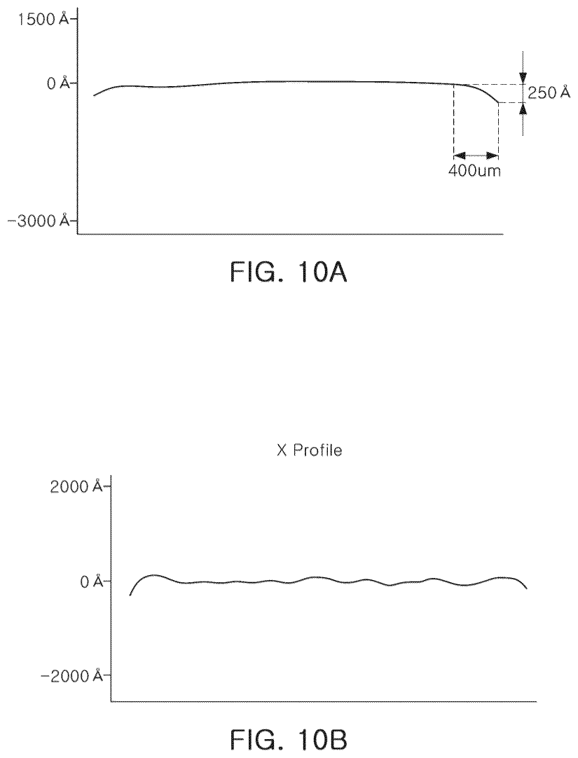

FIG. 7 is a view illustrating a surface morphology of a second semiconductor chip 100B of FIG. 5 as an uppermost semiconductor chip, and FIG. 9 is a view illustrating a surface morphology of an upper surface of a cover chip 100C of FIG. 5 introduced on the uppermost semiconductor chip. FIGS. 8A and 8B are views illustrating surface roughness along an upper surface of the second semiconductor chip of FIG. 7 in an X-axis and a Y-axis, and FIG. 10A and FIG. 10B are views illustrating surface roughness along an upper surface of the cover chip of FIG. 9 in the X-axis and Y-axis.

Since the thicknesses of the first semiconductor chips 100A1, 100A2 and 100A3 and the second semiconductor chip 100B are thin (e.g., 50 μm or less), in the process of stacking by hybrid bonding, surface topologies of each chip may be accumulated, and a surface topology of the second semiconductor chip 100B, which is an uppermost semiconductor chip, may be significantly increased.

In addition to FIG. 7, referring to FIG. 8A and FIG. 8B, a topology of an upper surface of the second semiconductor chip 100B is increased by a maximum range of 3000 Å to 5000 Å. Because a thin semiconductor chip has certain flexibility, the thin semiconductor chip may obtain desired bonding through an annealing process, but since a thick dummy chip 200 may be less flexible, it may be difficult to obtain the desired bond by causing voids.

In a state in which the cover chip 100C is stacked on an upper surface of the second semiconductor chip 100B, a surface morphology may be greatly improved by polishing an upper surface of the cover chip 100C. Referring to FIGS. 9, 10A, and 10B, an improved surface morphology of the cover chip 100C is illustrated. Only an edge region R of the upper surface of the cover chip 100C has a rounded shape, and a main region P thereof may have a high planarization. Such a high planarization may ensure a solid inter-dielectric bond between the cover chip 100C and the thick upper dummy chip 200.

The above-described example embodiments may be advantageously applied to a semiconductor package having various structures. The semiconductor packages 500 and 500A according to the previous example embodiments have illustrated a form including a base structure similar to an interposer, but the base structure may be implemented as a structure having a semiconductor chip.

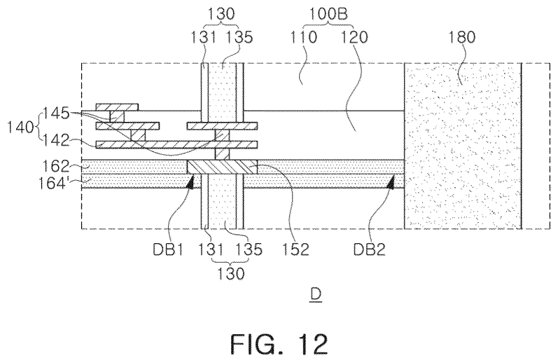

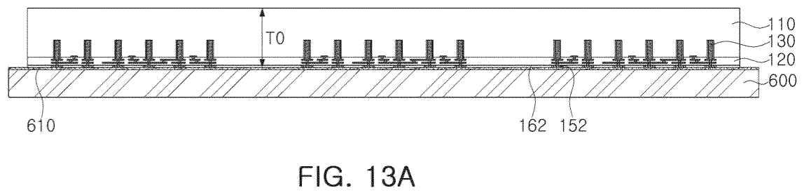

FIG. 11 is a side cross-sectional view illustrating a semiconductor package according to an example embodiment of the present disclosure, and FIG. 12 is a partially enlarged view illustrating part “D” of FIG. 11.

Referring to FIGS. 11 and 12, a semiconductor package 500B according to an example embodiment may be understood as a structure similar to that of the example embodiment illustrated in FIGS. 1 to 4 except that a base structure is implemented as a structure having a semiconductor chip, and that intermetallic bonding is directly bonded to lower pads and an upper end of a through silicon via (TSV). Accordingly, the description of example embodiments illustrated in FIGS. 1 to 4 may be combined with the description of an example embodiment unless otherwise described.

A base structure 300′ adopted in an example embodiment may include a semiconductor substrate (i.e., a substrate main body) 310, a device layer 220, a through-via 330, and a lower connection pad 352, similarly to the first semiconductor chips 100A1, 100A2 and 100A3. For example, the device layer 320 may include a logic element. The base structure 300′ may have a larger area than the first semiconductor chips 100A1, 100A2 and 100A3.

However, unlike the previous example embodiment, an intermetallic bonding DB1 introduced in this example embodiment may be directly bonded to lower pads 152 adjacent to a through silicon via (TSV) 130 without upper pads.

Specifically, as illustrated in FIG. 12, the through silicon via (TSV) 130 may penetrate through an upper insulating layer 164′. In an embodiment, the through silicon via (TSV) 130 may have an upper surface substantially coplanar with an upper surface of the upper insulating layer 164′. In this example embodiment, without separate upper pads, the through silicon via (TSV) 130 may perform intermetallic bonding DB1 to the lower pads 152 of the semiconductor chip 100A2 disposed thereon. Adjacent first semiconductor chips 100A1 and 100A2 may be bonded by inter-dielectric bonding DB2 of an upper insulating layer 164 and a lower insulating layer 162.

Similarly thereto, the through via 330 of the base structure 300′ and the lower pads 152 of the first semiconductor chip 100A1 may be directly bonded to each other, and an upper bonding insulating layer 364 of the base structure 300′ may be directly bonded to the lower insulating layer 162 of the first semiconductor chip 100A1.

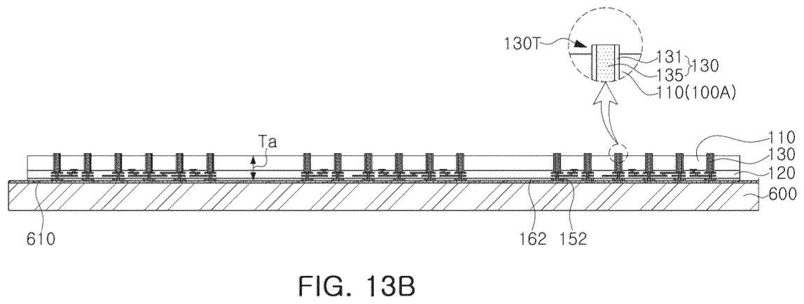

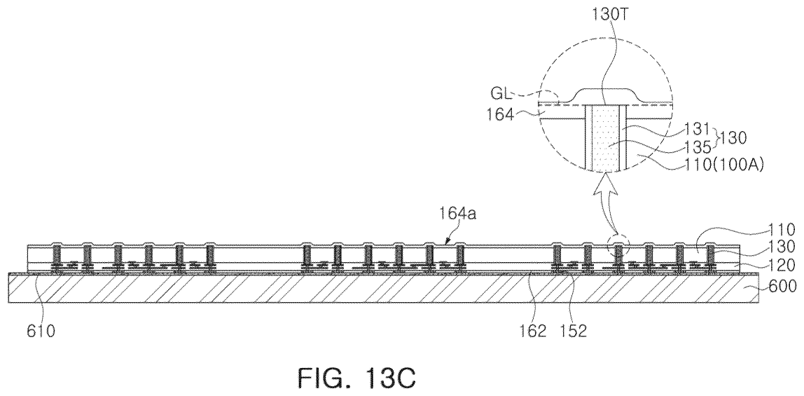

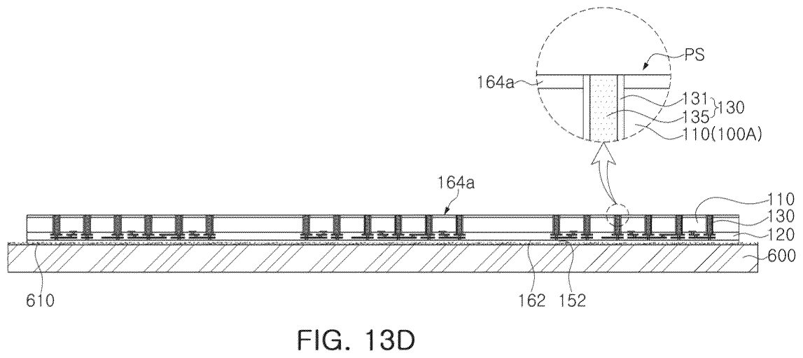

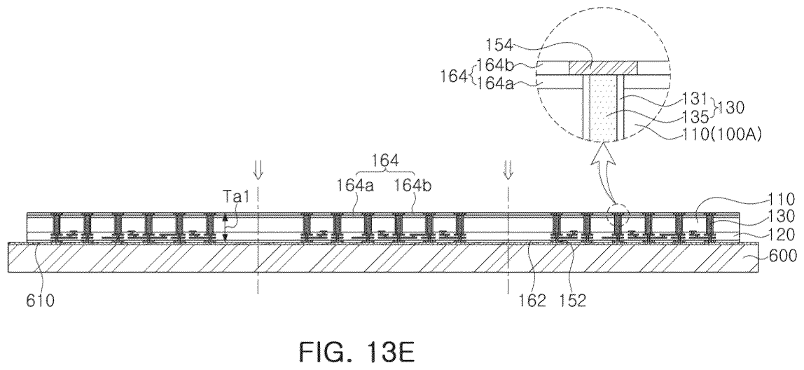

A method of manufacturing a semiconductor package according to an example embodiment may be described with reference to FIGS. 13A to 13E and 14A to 14G. FIGS. 13A to 13E are cross-sectional views for each main stage of a method of manufacturing a semiconductor chip (particularly, a first semiconductor chip) adopted in an example embodiment of the present disclosure, and FIGS. 14A to 14G are cross-sectional views for each main stage of a method of manufacturing a semiconductor package according to an example embodiment of the present disclosure.

Referring to FIG. 13A, a semiconductor substrate 110 for a plurality of first semiconductor chips 100A is bonded onto a carrier substrate 600.

For convenience of explanation, the semiconductor substrate 110 is illustrated as a wafer including three first semiconductor chips 100A. A plurality of first semiconductor chips may include individual devices on an active surface of the semiconductor substrate 110. Furthermore, a plurality of first semiconductor chips may further include through silicon vias (TSV) 130 penetrating the semiconductor substrate 110, a device layer 120 connected to the through silicon vias (TSV) 130, and lower pads 152 electrically connected to the through silicon vias (TSV) on the device layer 120. As described above, the semiconductor substrate 110 may be understood not to perform a backside process after completing a front process of a first semiconductor chip. That is, since a grinding process is not applied to the semiconductor substrate 110, the semiconductor substrate 110 may have a relatively large first thickness TO. The active surface of the semiconductor substrate 110, that is, a surface on which the device layer is formed, is bonded to face the carrier substrate 600. Such bonding may be implemented by an adhesive layer 610 such as a UV curable film.

Referring to FIG. 13B, in order to reduce a thickness (TO→Ta) of the semiconductor substrate 110, a grinding process is applied to an non-active surface of the semiconductor substrate 110.

In this grinding, an upper end 130T of a through silicon via (TSV) 130 may be exposed from a ground surface of a semiconductor wafer. Due to a difference in an etching rate, the upper end 130T may protrude from the surface of the semiconductor wafer 100. Through this process, a thickness of the first semiconductor chip 100A may be reduced by a desired thickness Ta. Such a thickness reduction process may also be performed by an etch-back process or a combination thereof, in addition to the grinding processes such as chemical mechanical polishing (CMP). In an embodiment, a grinding process may be performed to reduce the thickness of the semiconductor substrate 110, and the through silicon via (TSV) 130 may be sufficiently exposed by applying an etch-back process under appropriate conditions.

Referring to FIG. 13C, a first insulating film 164a may be formed on the semiconductor substrate 110 to cover the exposed upper end 130T of the through silicon via (TSV) 130.

The first insulating film 164a may be used as a passivation layer. For example, the first insulating film 164a may include silicon nitride or silicon oxynitride.

Referring to FIG. 13D, the first insulating film 164a may be ground so that the through silicon via (TSV) 130 is exposed.

The grinding process may be performed up to a predetermined line GL so that the first insulating film 164a is partially removed to sufficiently expose the through silicon via (TSV) 130. Through this grinding process, the first insulating film 164a may have an upper surface substantially coplanar with an upper surface of the through silicon via (TSV) 130. Furthermore, a damaged portion of the upper end 130T of the through silicon via (TSV) 130 may be removed.

Referring to FIG. 13E, upper pads 154 and a second insulating film 164b surrounding the upper pads 154 may be formed on the first insulating film 164a.

Similarly to the previous processes, the upper pads 154 are formed on the first insulating film 164a, and a second insulating film 164b is formed to cover the upper pads 154. Then, a grinding process may be performed so that the second insulating film 164b is partially removed to expose upper surfaces of the upper pads 154. Through this grinding process, the second insulating film 164b may have an upper surface substantially coplanar with the upper surfaces of the upper pads 154. For example, the second insulating film 164b may include silicon oxide. In the present specification, the first and second insulating layers 164a and 164b are collectively referred to as an upper insulating layer 164.

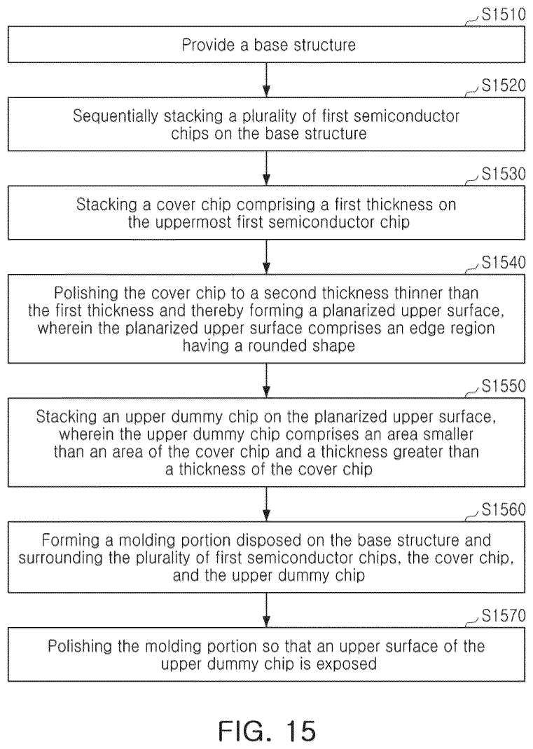

FIGS. 14A to 14G are cross-sectional views for each main stage of a method of manufacturing a semiconductor package according to an example embodiment of the present disclosure. FIG. 15 is a flowchart describing a method of manufacturing a semiconductor package according to an example embodiment of the present disclosure.

Referring to FIG. 14A, a base structure 300W having upper connection pads 354 and lower connection pads 352 is provided (S1510).

For convenience of explanation, the base structure 300W is illustrated in a form for manufacturing three semiconductor packages. The base structure 300W may include an upper bonding insulating layer 364 surrounding the upper connection pads 354 on an upper surface thereof. The upper bonding insulating layer 364 may have an upper surface substantially coplanar with upper surfaces of the upper connection pads 354. A connection bump 370 such as a solder ball may be formed on the lower connection pads 352 of the base structure 300W. Furthermore, in this example embodiment, the base structure 300W is illustrated as an interposer having an internal circuit for electrically connecting the upper connection pads 354 and the lower connection pads 352, but the base structure 300W may be in the form of a logic chip or a memory chip, respectively.

Referring to FIG. 14B, individualized first semiconductor chips 100A1 are disposed on the base structure 300W.

The first semiconductor chips 100A1 may be semiconductor chips obtained in the process of FIG. 13E. The first semiconductor chips 100A1 may include lower pads 152, upper pads 154, and through silicon vias (TSV) 130 for electrically connecting the lower pads 152 and the upper pads 154. Furthermore, the first semiconductor chips 100A1 may include a lower insulating layer 162 disposed on the lower surface and surrounding side surfaces of the lower pads 152, and an upper insulating layer 164 disposed on the upper surface and surrounding side surfaces of the upper pads 154. The stacking process may perform pre-bonding by applying a certain pressure using a bonding tool BT. Specifically, the lower pads 152 of the first semiconductor chips 100A1 may be pre-bonded directly to the upper connection pads 354 of the base structure 300, respectively, and similarly, the lower insulating layer 162 of the first semiconductor chips 100A1 may be pre-bonded directly to the upper bonding insulating layer 364 of the base structure 300.

Referring to FIG. 14C, additional first semiconductor chips 100A2 and 100A3 are sequentially stacked (S1520), and a second semiconductor chip 100C is disposed on uppermost first semiconductor chips 100A3 (S1530).

As a process similar to that of FIG. 14B, the additional first semiconductor chips 100A2 and 100A3 may be pre-bonded to other first semiconductor chips 100A1 and 100A2 disposed below them. Specifically, the lower pads 152 and the lower insulating layer 162 of each of the first semiconductor chips 100A2 and 100A3 may be pre-bonded directly to upper connection pads 354 and an upper bonding insulating layer 364 of the first semiconductor chips 100A1 and 100A2 stacked just before.

The second semiconductor chip 100C may be pre-bonded to the uppermost first semiconductor chip 100A3. Specifically, the lower pads 152 and the lower insulating layer 162 of the second semiconductor chip 100C may be pre-bonded directly to the upper connection pads 354 and the upper bonding insulating layer 364 of the uppermost first semiconductor chip 100A3, respectively.

The second semiconductor chip 100C introduced in this process is a cover chip and may have a first thickness TO′ greater than a thickness Ta of the first semiconductor chips 100A1, 100A2 and 100A3 in consideration of the thickness removed during planarization. For example, the first thickness TO′ of the second semiconductor chip 100C may be greater than the thickness Ta of the first semiconductor chips by 1 μm to 10 μm. Meanwhile, the first thickness TO′ of the stacked second semiconductor chip 100C may have a sufficient thickness for bonding in consideration of a surface topology of the uppermost first semiconductor chip. For example, the first thickness TO′ of the second semiconductor chip 100C may be 100 μm or less, and further, 80 μm or less.

An annealing process may be applied to the stacked first semiconductor chips 100A1, 100A2 and 100A3 and the second semiconductor chip 100C to form a solid intermetallic bond through diffusion of metal elements.

Referring to FIG. 14D, a process of planarizing an upper surface of the second semiconductor chip 100C is performed (S1540).

Such a planarization process may be performed by a grinding process and/or a CMP process. After the flattening process, the second semiconductor chip 100C may be reduced to a second thickness Tb less than the first thickness TO′. Since the stacked second semiconductor chips 100C are in an individualized state, an edge region of the upper surface may be overpolished. Accordingly, the planarized upper surface of the second semiconductor chip 100C may have an edge region having a rounded shape.

Referring to FIG. 14E, an upper insulating layer 174 may be formed on the planarized upper surface of the second semiconductor chip 100C. The upper insulating layer 174 is employed for inter-dielectric bonding with an upper dummy chip 200 of FIG. 14F. The upper insulating layer 174 may be formed by an additional deposition process, but in one or more embodiments, naturally formed natural oxide films may be replaced during other processes. When a high-temperature annealing process is performed after a planarization process, a desired upper insulating layer 174 may be formed in an oxygen atmosphere annealing process.

Referring to FIG. 14F, an upper dummy chip 200 may be stacked on the planarized upper surface of the second semiconductor chip 100C (S1550).

The upper dummy chip 200 has thicknesses greater than those of the first semiconductor chips 100A1, 100A2 and 100A3 and the second semiconductor chip 100C. For example, a thickness of the upper dummy chip 200 may be 200 μm or more. The upper dummy chip 200 may have an area smaller than an area of the second semiconductor chip 100C so as not to be disposed at a rounded edge region.

The upper dummy chip 200 may include a lower bonding insulating layer 210 disposed on an upper surface thereof. The lower bonding insulating layer 210 of the upper dummy chip 200 may be directly bonded to the upper bonding insulating layer 364 of the second semiconductor chip 100C.

Next, referring to FIG. 14G, a molding portion 180 surrounding the first semiconductor chips 100A1, 100A2 and 100A3, the second semiconductor chip 100C and the upper dummy chip 200 may be formed on the base structure 300 (S1560), and the molding portion may be polished so that the upper surface of the upper dummy chip 200 is exposed to an upper surface of the molding portion 180 (S1560). Furthermore, an identification mark may be formed on the upper surface of the upper dummy chip 200, or a heat radiating plate may be formed on the upper dummy chip 200 and the molding portion 180.

As the number of stacked semiconductor chips increases, a surface topology of an uppermost semiconductor chip may be accumulated and increased, and accordingly, when a thick dummy chip (e.g., 200 μm or more) is bonded to a surface thereof, bonding defects such as non-bonding or voids may occur, but the bonding defects may be eliminated by introducing a cover chip having a flat region, thereby providing a highly reliable semiconductor package structure.

Advantages and effects of the present application are not limited to the foregoing content and may be more easily understood in the process of describing a specific example embodiment of the present disclosure.

The present disclosure is not limited to the above-described embodiments and the accompanying drawings but is defined by the appended claims. Therefore, those of ordinary skill in the art may make various replacements, modifications, or changes without departing from the scope of the present disclosure defined by the appended claims, and these replacements, modifications, or changes should be construed as being included in the scope of the present disclosure.

1. A semiconductor package comprising:
a base structure comprising a lower surface with a lower connection pad thereon, and an upper surface with an upper connection pad thereon, wherein the upper connection pad is connected to the lower connection pad;
a plurality of first semiconductor chips stacked on the base structure in a vertical direction, wherein the plurality of first semiconductor chips comprises an uppermost first semiconductor chip and a lowermost first semiconductor chip, and wherein each of the plurality of first semiconductor chips comprises a first lower pad, a first upper pad, and a through silicon via connecting the first lower pad to the first upper pad;
a cover chip on the plurality of first semiconductor chips, the cover chip comprising an upper surface, wherein the upper surface comprises a flat region and an edge region having a rounded shape, and wherein the edge region is disposed around the flat region; and
an upper dummy chip disposed on the flat region of the cover chip, the upper dummy chip comprising an area smaller than an area of the cover chip and a thickness greater than a thickness of the cover chip,
wherein the first lower pad of the lowermost first semiconductor chip is directly connected to the upper connection pad, and
wherein the first upper pad of each of the plurality of first semiconductor chips, except for the uppermost first semiconductor chip, is directly connected to the first lower pad of another first semiconductor chip, among the plurality of first semiconductor chips, adjacent thereto.

2. The semiconductor package of claim 1, wherein the base structure further comprises a first area, and wherein each of the plurality of first semiconductor chips comprises a second area smaller than the first area.

3. The semiconductor package of claim 2, further comprising:
a molding portion disposed on the base structure and surrounding the plurality of first semiconductor chips, the cover chip, and the upper dummy chip.

4. The semiconductor package of claim 3, wherein an upper surface of the upper dummy chip is substantially coplanar with an upper surface of the molding portion.

5. The semiconductor package of claim 1,
wherein each of the plurality of first semiconductor chips further comprises:
a first lower insulating layer on a lower surface thereof and surrounding a side surface of the first lower pad; and
a first upper insulating layer disposed on an upper surface thereof and surrounding a side surface of the first upper pad, and
wherein the first upper insulating layer of each the plurality of first semiconductor chips is directly bonded to the first lower insulating layer of another first semiconductor chip, among the plurality of first semiconductor chips, adjacent thereto.

6. The semiconductor package of claim 5,
wherein the base structure further comprises a bonding insulating layer on the upper surface and surrounding a side surface of the upper connection pad, and
wherein the first lower insulating layer of the lowermost first semiconductor chip is directly bonded to the bonding insulating layer.

7. The semiconductor package of claim 1,
wherein the cover chip comprises a second semiconductor chip comprising a second lower pad, and
wherein the second lower pad is directly bonded to the first upper pad of the uppermost first semiconductor chip.

8. The semiconductor package of claim 7, wherein the second semiconductor chip is of the same type as the plurality of first semiconductor chips.

9. The semiconductor package of claim 1, further comprising:
a second semiconductor chip disposed between the uppermost first semiconductor chip and the cover chip, the second semiconductor chip comprising a second lower pad on a lower surface thereof,
wherein the second lower pad of the second semiconductor chip is directly bonded to the first upper pad of the uppermost first semiconductor chip.

10. The semiconductor package of claim 9, wherein the cover chip further comprises a lower dummy chip.

11. The semiconductor package of claim 1, wherein the base structure further comprises an interposer substrate comprising an internal wiring layer connecting the lower connection pad to the upper connection pad.

12. The semiconductor package of claim 1, wherein the base structure further comprises a lower semiconductor chip comprising a through-via connecting the lower connection pad to the upper connection pad.

13. The semiconductor package of claim 12, wherein each of the plurality of first semiconductor chips comprises a memory chip, and
wherein the lower semiconductor chip comprises a memory control chip.

14. A semiconductor package comprising:
a base structure comprising a lower surface with a lower connection pad thereon, and an upper surface with an upper connection pad thereon, wherein the upper connection pad is connected to the lower connection pad;
a plurality of first semiconductor chips stacked on the base structure in a vertical direction, wherein the plurality of first semiconductor chips comprises an uppermost first semiconductor chip and a lowermost first semiconductor chip, and wherein each of the plurality of first semiconductor chips comprise a first lower pad, a first upper pad, and a through silicon via (TSV) connecting the first lower pad and the first upper pad;
a second semiconductor chip on the uppermost first semiconductor chip, the second semiconductor chip comprising: a second lower pad directly bonded to the first upper pad of the uppermost first semiconductor chip; and an upper surface comprising a flat region and an edge region having a rounded shape, wherein the edge region is disposed around the flat region; and
an upper dummy chip on the flat region of the second semiconductor chip, the upper dummy chip comprising an area smaller than an area of the second semiconductor chip and a thickness greater than a thickness of the second semiconductor chip,
wherein the first lower pad of the lowermost first semiconductor chip is directly connected to the upper connection pad, and
wherein the first upper pad of each of the plurality of first semiconductor chips, except for the uppermost first semiconductor chip, is directly connected to the first lower pad of another first semiconductor chip, among the plurality of first semiconductor chips, adjacent thereto.

15. The semiconductor package of claim 14,
wherein the base structure further comprises an upper bonding insulating layer on the upper surface and surrounding a side surface of the upper connection pad,
wherein each of the plurality of first semiconductor chips further comprises:
a first lower insulating layer on a lower surface thereof and surrounding a side surface of the first lower pad; and
a first upper insulating layer on an upper surface thereof and surrounding a side surface of the first upper pad,
wherein the first lower insulating layer of the lowermost first semiconductor chip is directly bonded to the upper bonding insulating layer, and
wherein the first upper insulating layer of each of the plurality of first semiconductor chips, except for the uppermost first semiconductor chip, is directly bonded to the first lower insulating layer of another first semiconductor chip, among the plurality of first semiconductor chips, adjacent thereto.

16. The semiconductor package of claim 15,
wherein the second semiconductor chip comprises a second lower insulating layer on a lower surface thereof and surrounding a side surface of the second lower pad, and a second upper insulating layer on an upper surface thereof, and
wherein the second lower insulating layer of the second semiconductor chip is directly bonded to the first lower insulating layer of the uppermost first semiconductor chip.

17. The semiconductor package of claim 16, wherein the upper dummy chip comprises a lower bonding insulating layer to which the second upper insulating layer is directly bonded.

18. A semiconductor package comprising:
a base structure comprising a lower surface with a lower connection pad thereon, and an upper surface with an upper connection pad thereon, wherein the upper connection pad is connected to the lower connection pad;
a plurality of first semiconductor chips stacked on the base structure in a vertical direction, wherein the plurality of first semiconductor chips comprises an uppermost first semiconductor chip and a lowermost first semiconductor chip, and wherein each of the plurality of first semiconductor chips comprise a first lower pad, a first upper pad, and a through silicon via connecting the first lower pad to the first upper pad;
a second semiconductor chip disposed on the uppermost first semiconductor chip, the second semiconductor chip comprising a second lower pad directly bonded to the first upper pad of the uppermost first semiconductor chip;
a lower dummy chip disposed on the second semiconductor chip, the lower dummy chip comprising an upper surface, wherein the upper surface comprises a flat region and an edge region having a rounded shape, and wherein the edge region is disposed around the flat region; and
an upper dummy chip disposed on the flat region of the lower dummy chip, the upper dummy chip comprising an area smaller than an area of the lower dummy chip and a thickness greater than a thickness of the second semiconductor chip,
wherein the first lower pad of the lowermost first semiconductor chip is directly bonded to the first upper pad, and
wherein the first upper pad of each the plurality of first semiconductor chips, except for the uppermost first semiconductor chip, is directly bonded to the first lower pad of another first semiconductor chip, among the plurality of first semiconductor chips, adjacent thereto.

19. The semiconductor package of claim 18,
wherein the base structure further comprises an upper bonding insulating layer disposed on the upper surface and surrounding a side surface of the upper connection pad,
wherein each of the plurality of first semiconductor chips further comprises:
a first lower insulating layer on a lower surface thereof and surrounding a side surface of the first lower pad; and
a first upper insulating layer on an upper surface thereof and surrounding a side surface of the first upper pad,
wherein the first lower insulating layer of the lowermost first semiconductor chip is directly bonded to the upper bonding insulating layer, and
wherein the first upper insulating layer of each the plurality of first semiconductor chips, except for the uppermost first semiconductor chip, is directly bonded to the first lower insulating layer of another first semiconductor chip, among the plurality of first semiconductor chips, adjacent thereto.

20. The semiconductor package of claim 19,
wherein the second semiconductor chip further comprises:
a second lower insulating layer on a lower surface thereof and surrounding a side surface of the second lower pad, and
a second upper insulating layer on an upper surface thereof, and
wherein the second lower insulating layer is directly bonded to the first lower insulating layer of the uppermost first semiconductor chip.

21-24. (canceled)
